(19) United States
(12) Patent Application Publication
(10) Pub. No.: US 2026/0136491 A1
(43) Pub. Date: May 14, 2026

(54) INTEGRATED COLD PLATE COOLING DEVICE

(71) Applicant: Delta Electronics, Inc., Taoyuan City (TW)

(72) Inventors: Ming-Kun Tsai, Taoyuan City (TW); Shih-Kai Chien, Taoyuan City (TW); Ming-Tsung Lee, Taoyuan City (TW)

(21) Appl. No.: 19/343,867

(22) Filed: Sep. 29, 2025

Related U.S. Application Data
(60) Provisional application No. 63/718,798, filed on Nov. 11, 2024.

(30) Foreign Application Priority Data
Sep. 12, 2025 (CN) 202511302058.6

(51) Int. Cl. H05K 7/20; H05K 1/02

(52) U.S. Cl. CPC H05K 7/20254; H05K 1/0203; H05K 7/20272; H05K 7/20436; H05K 2201/066

(57) ABSTRACT

An integrated cold plate cooling device is disclosed and includes a base plate and a cover plate. The base plate includes a top surface, a bottom surface and plural heat dissipation fins. The top surface and the bottom surface are arranged opposite to each other in a first direction, the bottom surface is thermally coupled to plural heat sources, and the plural heat dissipation fins are arranged on the top surface. The cover plate includes an inlet, an outlet and plural turbulence generators. When the cover plate is assembled to the top surface of the base plate along the first direction, plural chambers are formed. The plural chambers are configured to respectively accommodate the plural heat dissipation fins and in communication between the inlet and the outlet. The plural turbulence generators are correspondingly arranged between the plural heat dissipation fins and the inlet.

### CROSS-REFERENCE TO RELATED APPLICATION

This application claims the benefit of U.S. Provisional Application No. 63/718,798 filed on November 11, 2024, and entitled “COLD PLATE COOLING DEVICE”. This application claims priority to China Patent Application No. 202511302058.6, filed on September 12, 2025. The entireties of the above-mentioned patent applications are incorporated herein by reference for all purposes.

### FIELD OF THE INVENTION

The present disclosure relates to a heat dissipation device, and more particularly to an integrated cold plate cooling device, which enhances the heat transfer effect and reasonably distributes the coolant flow by setting turbulence generators, so that the overall cooling efficiency and the system reliability are improved.

### BACKGROUND OF THE INVENTION

Currently, in multi-chip packaging designs, multiple chips are typically mounted simultaneously on the same printed circuit board (PCB), and each chip requires a separate cold plate or a heat sink module for heat dissipation. However, a cumbersome installation process is required to correspondingly install multiple cold plates or heat sink modules on the heat sources of the multiple chips. Furthermore, the design of the water connections between the multiple cold plates or heat sink modules is quite complex, and it increases the risk of coolant leakage and results in device performance damage.

Therefore, there is a need of providing an integrated cold plate cooling device. A plurality of turbulence generators are arranged to enhance the heat transfer effect and reasonably distribute the coolant flow by setting turbulence generators, so that the overall cooling efficiency and the system reliability are improved.

### SUMMARY OF THE INVENTION

An object of the present disclosure is to provide an integrated cold plate cooling device. A plurality of turbulence generators are arranged to enhance the heat transfer effect and reasonably distribute the coolant flow by setting turbulence generators, so that the overall cooling efficiency and the system reliability are improved.

Another object of the present disclosure is to provide an integrated cold plate cooling device. An integrally formed metal base plate and an integrally formed plastic cover plate are tightly combined through a rubber sealing element to form a plurality of chambers in communication between an inlet and an outlet of the plastic cover plate, and simultaneously dissipate the heat from a plurality of heat sources installed on one single printed circuit board. The plurality of heat sink fins are arranged corresponding to the plurality of heat sources, so that the thermal coupling is achieved effectively. Since the plastic cover is easy to design and change the flow path, the turbulence generators are set and corresponding to the positions of the plurality of heat sink fins in the cooling chamber. The plurality of turbulence generators protrude downward from the bottom surface of the plastic cover and are located at least at a leading edge of the flow channel in communication between each of the plurality of chambers and the inlet. In other words, each turbulence generator is correspondingly positioned between each of the plurality of heat sink fins and the inlet, so as to generate the turbulence effectively to enhance the heat transfer. The turbulence generator disposed on the plastic cover is composed of multiple protruding features, which can effectively generate turbulence to enhance the heat transfer effect. The structure unit of the turbulence generator includes a square column, a triangular column, a quadrilateral column, a polygonal column, a circular column, a cone, a round-headed column, an inclined column, a wing-shaped column, a curved fin, a transverse rib, an inclined rib, a V-shaped rib, or a W-shaped rib. The cross-section of the rib structure can be, for example, square, triangle, right triangle, rounded rectangle or arc. The style, the quantity and the arrangement can be combined and varied according to the practical requirements. In addition, the turbulence generators are placed at the entrance of the heat-sink-fin area or in the spaced region between the heat sink fins in the chamber. By adjusting the style, the number and the arrangement of the turbulence generators, the pressure drop in the chamber with the heat-sink-fin area can be controlled, thereby achieving a reasonable distribution of the coolant flow. Furthermore, the turbulence generator can be a movable structure, allowing adjusting the direction or the position according to the flow rate or the pressure drop. On the other hand, the outlet for the coolant can be arranged in multiple locations to match the heat source of the chip layout, but is not limited thereto. Furthermore, the coolant flowing between the inlet and the outlet is not limited to a single-phase cooling fluid, such as water or oil. It can also be a two-phase coolant, such as a refrigerant, to improve the cooling efficiency of the heat dissipation device through phase change. Certainly, the present disclosure is not limited thereto.

In accordance with an aspect of the present disclosure, an integrated cold plate cooling device is provided and includes a base plate and a cover plate. The base plate includes a top surface, a bottom surface and a plurality of heat dissipation fins. The top surface and the bottom surface are arranged opposite to each other in a first direction, the bottom surface is thermally coupled to a plurality of heat sources, and the plurality of heat dissipation fins are arranged on the top surface and spatially corresponding to the plurality of heat sources. The cover plate includes an inlet, at least one outlet and a plurality of turbulence generators. The cover plate is assembled to the top surface of the base plate along the first direction, and a plurality of chambers are formed. The plurality of chambers are configured to respectively accommodate the plurality heat dissipation fins and in communication between the inlet and the at least one outlet. The plurality of turbulence generators protrude from the cover plate toward the base plate, and each of the plurality of turbulence generators is correspondingly arranged between one of the plurality of heat dissipation fins and the inlet.

In an embodiment, the base plate is formed by integrally molding a metal material, and the cover plate is formed by integrally molding a plastic material.

In an embodiment, the plurality of heat dissipation fins and the plurality of heat sources are overlapped in view of the first direction.

In an embodiment, the plurality of heat dissipation fins and the plurality of turbulence generators are misaligned in view of the first direction.

In an embodiment, a coolant flows through the plurality of chambers along a second direction respectively, and the second direction is perpendicular to the first direction, wherein the plurality of heat dissipation fins are extended along the second direction, and openings of the inlet and the at least one outlet face the first direction.

In an embodiment, the cover plate includes an outer peripheral wall, which is tightly combined with the base plate through a rubber sealing element.

In an embodiment, the plurality of turbulence generators includes at least one rib structure selected from the group consisting of a transverse rib, an inclined rib, a V-shaped rib, a W-shaped rib and a combination thereof.

In an embodiment, the at least one rib structure includes a cross-section selected from one of the group consisting of a square, a rectangle, a triangle, a right triangle, a rounded rectangle and a combination thereof, the plurality of heat dissipation fins are extended along a second direction, the second direction is perpendicular to the first direction, and an extension direction of the at least one rib structure is not parallel to the second direction.

In an embodiment, a tip is formed at the middle section of each of the V-shaped ribs, and the tip faces the inlet or the at least one outlet.

In an embodiment, a tip is formed at the middle section of each of the W-shaped ribs, and the tip faces the inlet or the at least one outlet.

In an embodiment, the plurality of turbulence generators includes a plurality of column structures selected from the group consisting of a square column, a triangular column, a quadrilateral column, a polygonal column, a circular column, a cone, a round-headed column, an inclined column, a wing-shaped column, an arc-shaped fin and a combination thereof.

In an embodiment, the plurality of column structures are arranged in an aligned array or a staggered array.

In an embodiment, a number of the at least one outlet is greater than a number of the inlet.

In an embodiment, a number of the at least one outlet is equal to a number of the plurality of chambers, a coolant flows through the plurality of chambers along a second direction and is discharged through a corresponding one of the at least one outlet, and the second direction is perpendicular to the first direction.

In an embodiment, a coolant flows through the plurality of chambers along a second direction, and the second direction is perpendicular to the first direction, wherein the plurality of heat dissipation fins are extended along the second direction in the plurality of chambers and segmented to form at least one spaced region, wherein one of the plurality of turbulence generators is located in the at least one spaced region.

In an embodiment, the at least one spaced region and the plurality of heat sources are overlapped in view of the first direction.

In an embodiment, the integrated cold plate cooling device further includes a plurality of leading channels, wherein the inlet is branched into the plurality of chambers through the plurality of leading channels.

In an embodiment, the integrated cold plate cooling device further includes a plurality of leading channels, wherein the plurality of leading channels are respectively arranged between a leading edge of each of the plurality of chambers and the inlet.

In an embodiment, a coolant flows through the plurality of chambers along a second direction, and the second direction being perpendicular to the first direction, wherein the plurality of chambers in communication between the inlet and the at least one outlet are symmetrically arranged, with a central axis of symmetry parallel to the second direction.

In an embodiment, the plurality of heat sources include a plurality of heat-generating chips mounted on a single printed circuit board, and the plurality of heat sources are directly thermally coupled to the bottom surface of the base plate.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a schematic structural view illustrating an integrated cold plate cooling device according to a first embodiment of the present disclosure;

FIG. 2 is a cross-sectional view of the integrated cold plate cooling device of FIG. 1 taken along line AA’;

FIG. 3A to FIG. 3D respectively illustrate exemplary rib structures of the turbulence generator in the present disclosure;

FIG. 4A to FIG. 4F illustrate exemplary cross-sectional views of the rib structures of the turbulence generator in the present disclosure;

FIG. 5A to FIG. 5F illustrate exemplary embodiments of the turbulence generator in the present disclosure, which includes the column structures arranged in an aligned array;

FIG. 6A to FIG. 6F illustrate exemplary embodiments of the turbulence generator in the present disclosure, which includes the column structures arranged in a staggered array;

FIG. 7 is a schematic structural view illustrating an integrated cold plate cooling device according to a second embodiment of the present disclosure;

FIG. 8 is a cross-sectional view of the integrated cold plate cooling device of FIG. 7 taken along line BB’;

FIG. 9 is a schematic structural view illustrating an integrated cold plate cooling device according to a third embodiment of the present disclosure;

FIG. 10 is a cross-sectional view of the integrated cold plate cooling device of FIG. 9 taken along line CC’;

FIG. 11 is a schematic structural view illustrating an integrated cold plate cooling device according to a fourth embodiment of the present disclosure; and

FIG. 12 is a cross-sectional view of the integrated cold plate cooling device of FIG. 11 taken along line DD’.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “top,” “bottom,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the "first," "second" and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, "and / or" and the like may be used herein for including any or all combinations of one or more of the associated listed items.

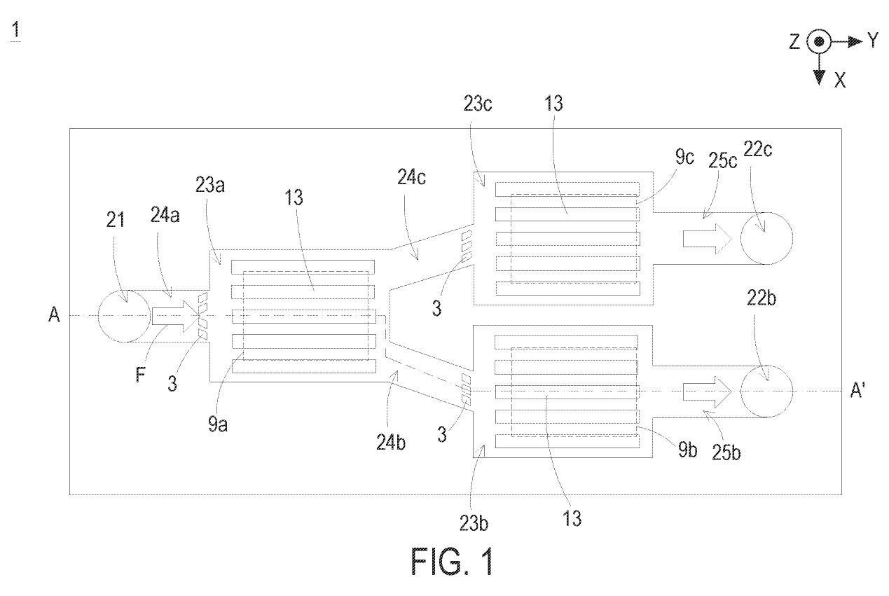

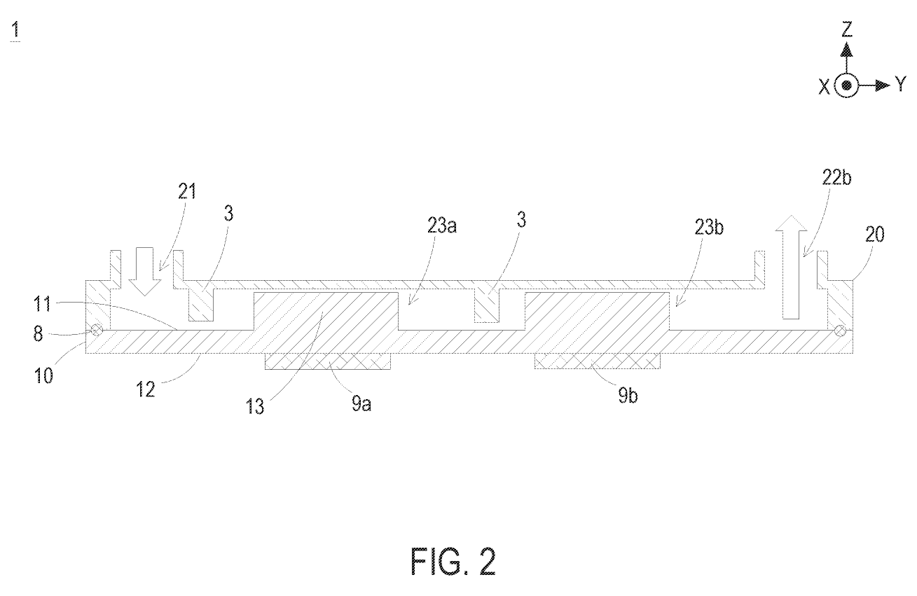

FIG. 1 is a schematic structural view illustrating an integrated cold plate cooling device according to a first embodiment of the present disclosure. FIG. 2 is a cross-sectional view of the integrated cold plate cooling device of FIG. 1 taken along line AA’. Please refer to FIG. 1 and FIG. 2. The present disclosure provides an integrated cold plate cooling device 1, which includes a base plate 10 and a cover plate 20. Preferably but not exclusively, the base plate 10 is formed by integrally molding a metal material, and the cover plate 20 is formed by integrally molding a plastic material. In the embodiment, the base plate 10 includes a top surface 11, a bottom surface 12 and a plurality of heat dissipation fins 13. The top surface and the bottom surface are arranged opposite to each other in a first direction (i.e., the Z axial direction). The bottom surface 12 is thermally coupled to a plurality of heat sources 9a, 9b, 9c. Notably, in the embodiment, the plurality of heat sources 9a, 9b, 9c refer to a plurality of heat-generating chips mounted on a single printed circuit board, such as a CPU and a GPU on the PCB, and the plurality of heat sources 9a, 9b, 9c are directly thermally coupled to the bottom surface 12 of the base plate 10. Certainly, the bottom surface 12 is not limited to a flat surface, so explain first. In the embodiment, the plurality of heat dissipation fins 13 are arranged on the top surface 11 of the base plate 10, and spatially corresponding to the plurality of heat sources 9a, 9b, 9c. In view of the first direction (i.e., the Z axial direction), the plurality of heat dissipation fins 13 and the plurality of heat sources 9a, 9b, 9c are overlapped. The cover plate 20 includes an inlet 21, at least one outlet 22b, 22c and a plurality of turbulence generators 3. In this embodiment, the cover plate 20 includes an outer peripheral wall, which is tightly combined with the base plate 10 along the first direction (i.e., the Z axial direction) through a rubber sealing element 8, such as an O-RING. Moreover, the cover plate 20 is assembled to the top surface 11 of the base plate 10. At the same time, a plurality of chambers 23a, 23b, 23c are formed between the cover plate 20 and the base plate 10. In the embodiment, the plurality of chambers 23a, 23b, 23c are configured to respectively accommodate the plurality heat dissipation fins 13 for dissipating generated heat therefrom. Moreover, the plurality of chambers 23a, 23b, 23c are allowed to be connected in series and/or in parallel between the inlet 21 and the at least one outlet 22b, 22c. In the embodiment, the inlet 21 is in communication with the chamber 23a through the leading channel 24a, the chamber 23a is in communication with the chambers 23b, 23c through the leading channels 24b, 24c, respectively, and the chambers 23b, 23c are in communication with the outlets 22b, 22c through the outlet channels 25b, 25c, respectively. After entering the inlet 21, the coolant (not shown) first flows through the chamber 23a in the second direction (i.e., the Y axial direction), then is branched through the leading channels 24b, 24c, flows through the chambers 23b, 23c in the second direction (i.e., the Y axial direction), and finally is discharged through the outlets 22b, 22c, respectively. The second direction is perpendicular to the first direction. Preferably but not exclusively, the integrated cold plate cooling device 1 is further designed in a symmetrical arrangement, with a central axis of symmetry parallel to the second direction, but the present disclosure is not limited thereto. In the embodiment, the plurality of heat dissipating fins 13 are extended along the second direction (i.e., the Y axial direction) parallel to the flow direction F of the coolant. Preferably but not exclusively, the openings of the inlet 21 and the outlets 22b, 22c face the first direction (i.e., the Z axial direction). Notably, in the embodiment, the plurality of turbulence generators 3 protrude from the cover plate 20 toward the base plate 10, and each of the plurality of turbulence generators 3 is correspondingly arranged between one of the plurality of heat dissipation fins 13 and the inlet 21. In view of the first direction (i.e., the Z axial direction), the plurality of heat dissipation fins 13 and the plurality of turbulence generators 3 are misaligned to each other. In other words, at least one turbulence generator 3 is arranged at a leading edge of the flow channel in each of the plurality of chambers 23a, 23b, 23c connected to the inlet 21, so that the turbulence is generated effectively, and the heat transfer effect of the plurality of heat sink fins 13 to the plurality of heat sources 9a, 9b, 9c is enhanced.

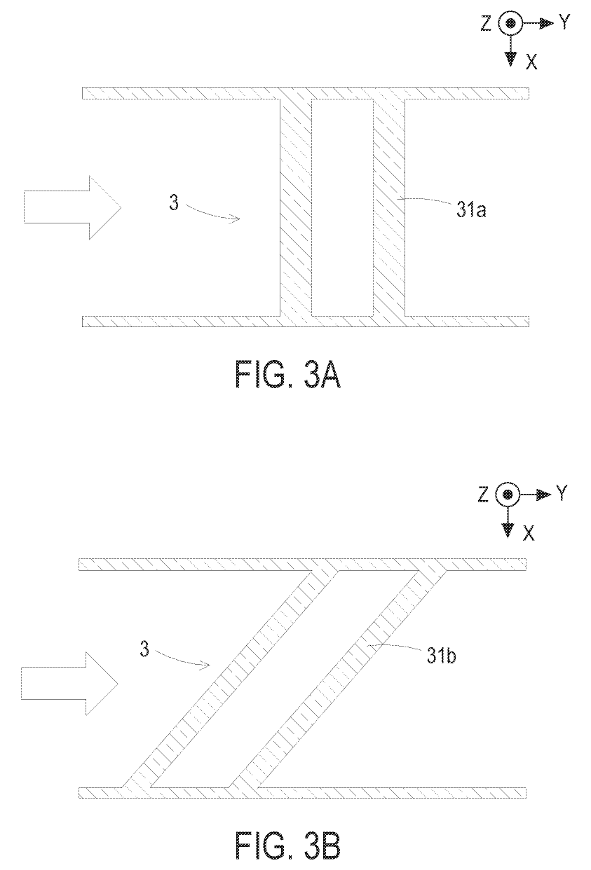

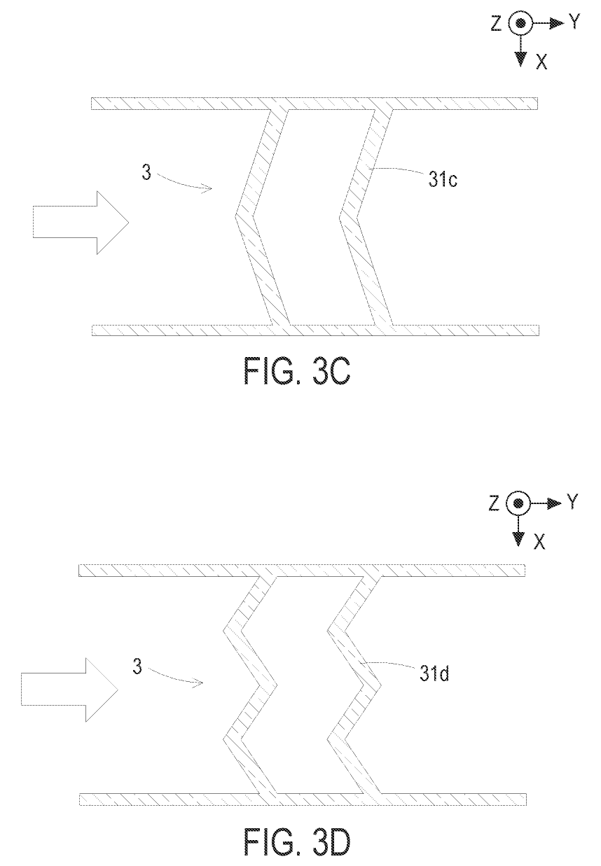

Notably, the turbulence generator 3 disposed on the cover plate 20 is composed of a plurality of protruding features, which can effectively generate the turbulence to enhance the heat transfer effect. The structure is not limited to one single type. FIG. 3A to FIG. 3D respectively illustrate exemplary rib structures of the turbulence generator in the present disclosure. In an embodiment, the turbulence generator 3 includes at least one rib structure on the cover plate 20. Preferably but not exclusively, as shown in FIG. 3A , the turbulence generator 3 includes a pair of transverse ribs 31a. By adjusting the protrusion height, the thickness and the number of the ribs, the pressure drop, the flow rate and the turbulence of the coolant entering the plurality of chambers 23a, 23b, 23c are controlled, thereby enhancing the heat dissipation effect of the heat dissipation fins 13 on the heat sources 9a, 9b, 9c. Preferably but not exclusively, as shown in FIG. 3B , the turbulence generator 3 includes a pair of inclined ribs 31b. By adjusting the protrusion height, the thickness and the number of the ribs, the pressure drop, the flow rate and the turbulence of the coolant entering the plurality of chambers 23a, 23b, 23c are controlled, thereby enhancing the heat dissipation effect of the heat dissipation fins 13 on the heat sources 9a, 9b, 9c. Preferably but not exclusively, as shown in FIG. 3C , the turbulence generator 3 includes a pair of V-shaped ribs 31c. A tip is formed at the middle section of each of the V-shaped ribs 31c, and the tip faces the inlet 21 or the at least one outlet 22b, 22c. By adjusting the protrusion height, the thickness, the tip direction and the number of the ribs, the pressure drop, the flow rate and the turbulence of the coolant entering the plurality of chambers 23a, 23b, 23c are controlled, thereby enhancing the heat dissipation effect of the heat dissipation fins 13 on the heat sources 9a, 9b, 9c. Preferably but not exclusively, as shown in FIG. 3D , the turbulence generator 3 includes a pair of W-shaped ribs 31d. A tip is formed at the middle section of each of the W-shaped ribs 31d, and the tip faces the inlet 21 or the at least one outlet 22b, 22c. By adjusting the protrusion height, the thickness, the tip direction and the number of the ribs, the pressure drop, the flow rate and the turbulence of the coolant entering the plurality of chambers 23a, 23b, 23c are controlled, thereby enhancing the heat dissipation effect of the heat dissipation fins 13 on the heat sources 9a, 9b, 9c. Certainly, the turbulence generator 3 in the above embodiments can be combined and varied, but not limited thereto.

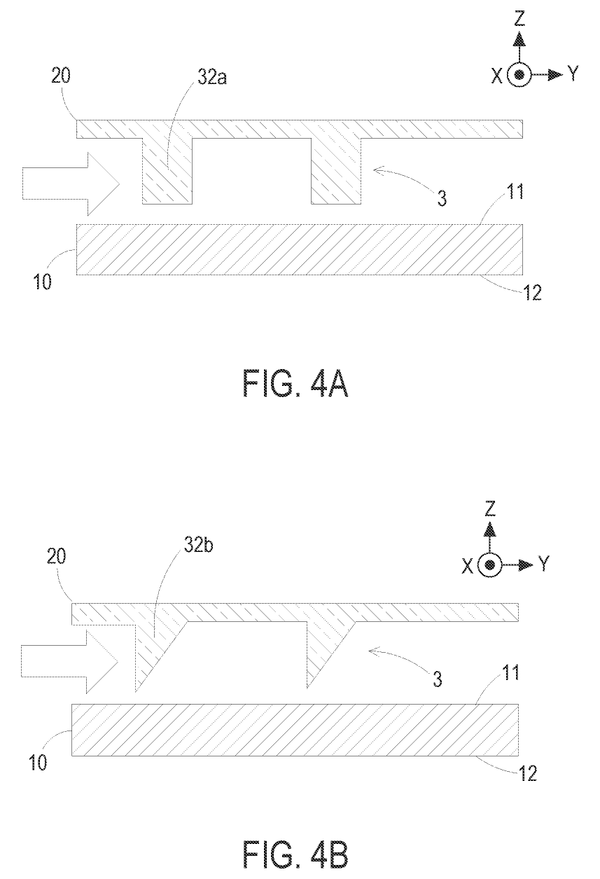

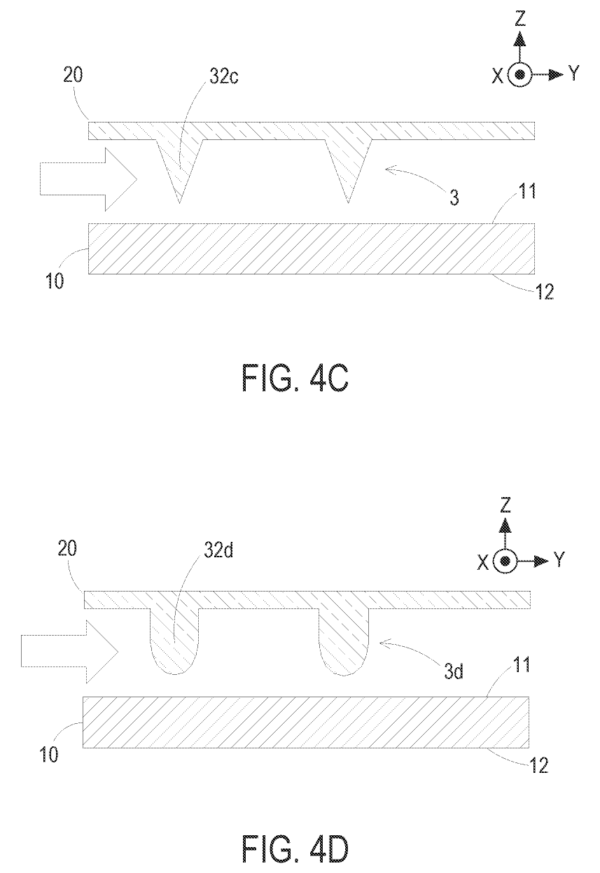

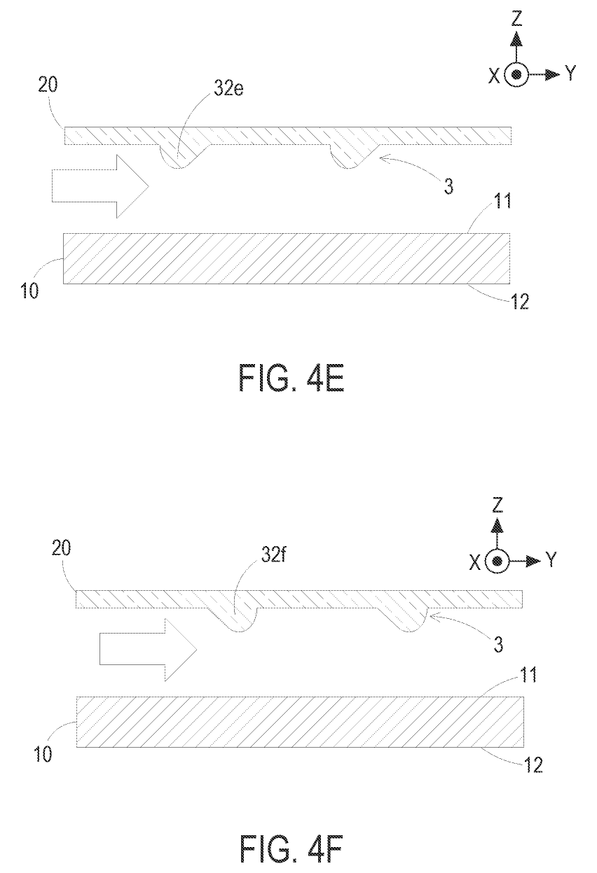

FIG. 4A to FIG. 4F illustrate exemplary cross-sectional views of the rib structures of the turbulence generator in the present disclosure. in addition to the main body of the aforementioned rib structure, the cross-section of the rib structure is also adjustable according the practical requirements. In the embodiment, the rib structure constituting the turbulence generator 3, can be for example but not limited to, a rectangular cross-section 32a (as shown in FIG. 4A), a right-angled triangle cross-section 32b (as shown in FIG. 4B), a triangle cross-section 32c (as shown in FIG. 4C), a rounded rectangle cross-section 32d (as shown in FIG. 4D), or different arc-shaped cross-sections 32e, 32f (as shown in FIG. 4E and FIG. 4F). Certainly, the cross-section of the rib structures of the turbulence generator 3 in the present disclosure can be combined and varied, but not limited thereto. Any configuration that can appropriately adjust the pressure drop and the flow rate of the coolant by selecting an appropriate cross-section of the rib structure is applicable to the present disclosure.

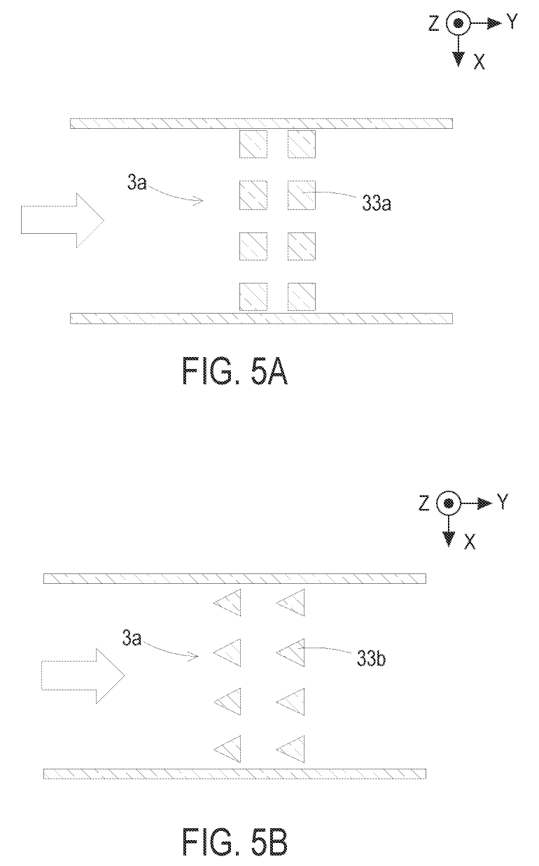

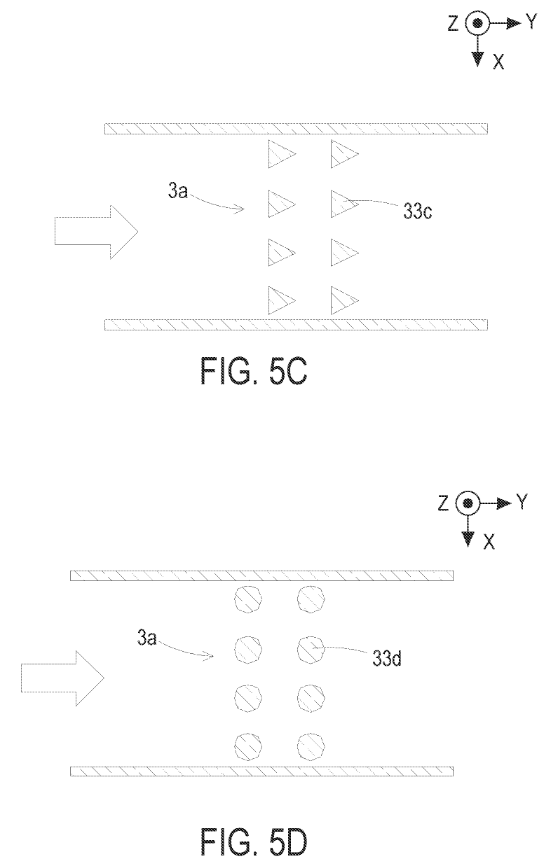

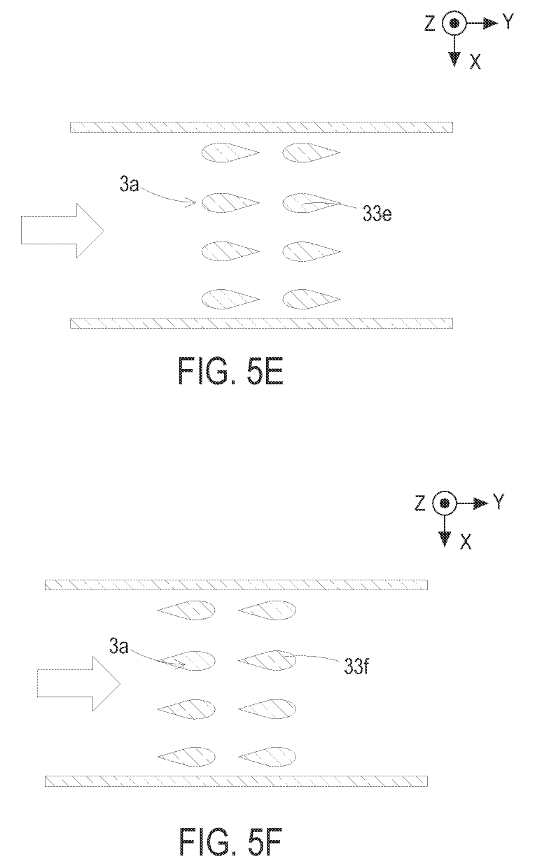

On the other hand, in an embodiment, the turbulence generator 3 can also be for example but not limited to a plurality of column structures on the cover plate 20, and the plurality of column structures are arranged in an aligned array. FIG. 5A to FIG. 5F illustrate exemplary embodiments of the turbulence generator in the present disclosure, which includes the column structures arranged in an aligned array. Preferably but not exclusively, in an embodiment, the turbulence generator 3 of the integrated cold plate cooling device 1 can be modified to the configuration of the turbulence generator 3a shown in FIG. 5A. The turbulence generator 3a includes a plurality of square columns 33a, which are arranged in pairs and in a front-to-back aligned arrangement. By adjusting the protrusion height, the size, the spaced distance and the number of the square columns 33a, the pressure drop, the flow rate and the turbulence of the coolant entering the plurality of chambers 23a, 23b, 23c are controlled, thereby enhancing the heat dissipation effect of the heat dissipation fins 13 on the heat sources 9a, 9b, 9c. Preferably but not exclusively, in an embodiment, the turbulence generator 3 of the integrated cold plate cooling device 1 can be modified to the configuration of the turbulence generator 3a shown in FIG. 5B or FIG. 5C, where the turbulence generator 3a includes a plurality of regular triangular columns 33b or inverted triangular columns 33c. By adjusting the protrusion height, the size, the spaced distance, the tip direction and the number of the triangular columns 33b, 33c, the pressure drop, the flow rate and the turbulence of the coolant entering the plurality of chambers 23a, 23b, 23c are controlled, thereby enhancing the heat dissipation effect of the heat dissipation fins 13 on the heat sources 9a, 9b, 9c. Preferably but not exclusively, in another embodiment, the turbulence generator 3 of the aforementioned integrated cold plate cooling device 1 can also be changed to the configuration of the turbulence generator 3a shown in FIG. 5D to FIG. 5F, where the turbulence generator 3a is replaced by a polygonal column 33d or different wing-shaped columns 33e, 33f to increase the diversity of modulating the pressure drop, the flow rate and the turbulence effects. Certainly, the plurality of column structures of the turbulence generator 3a can also be selected from a quadrangular column, a circular column, a cone, a round-headed column, an inclined column, an arc-shaped fin or other column structures, but the present disclosure is not limited thereto.

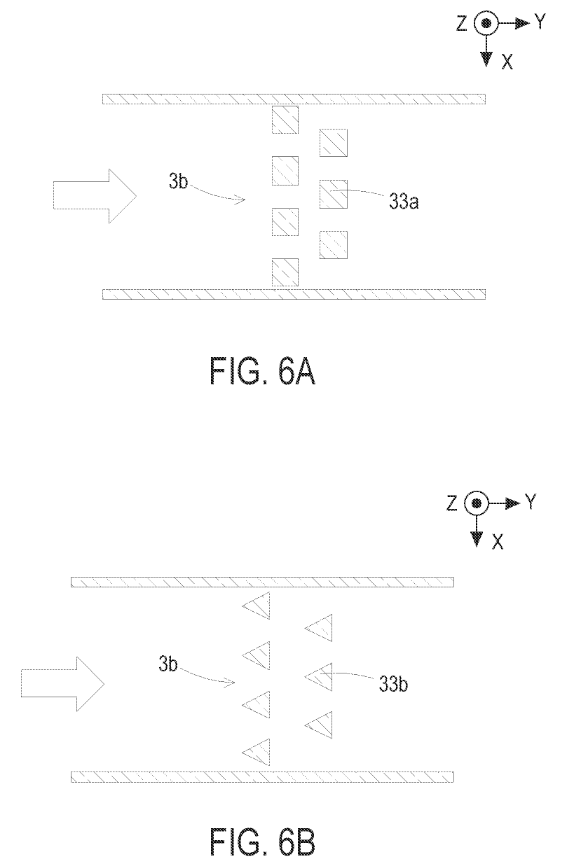

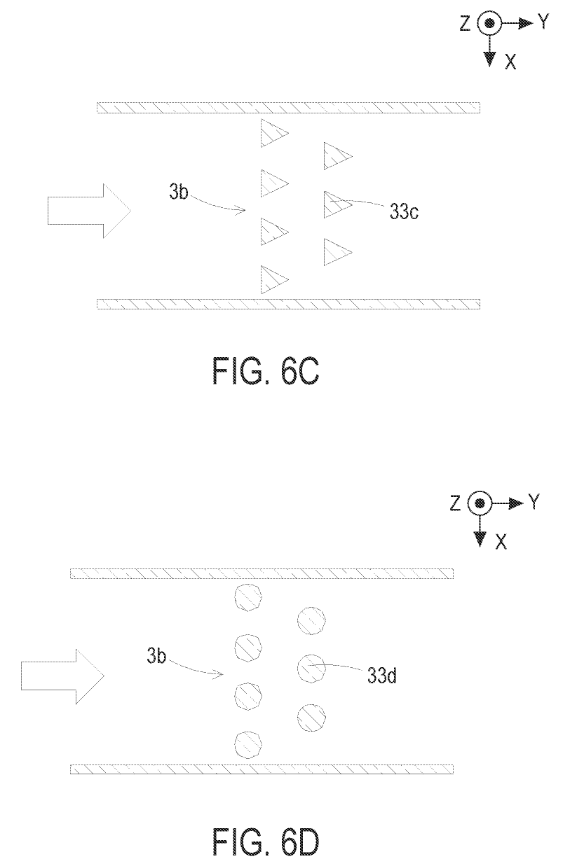

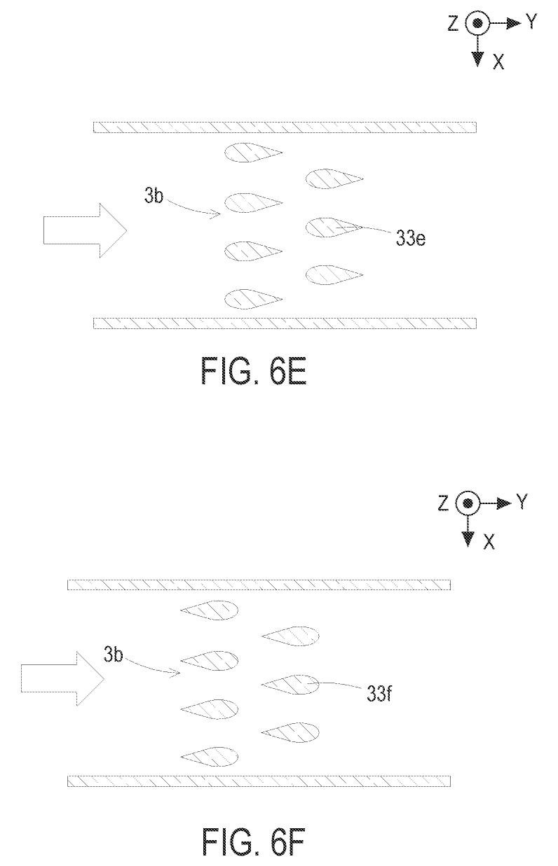

Furthermore, FIG. 6A to FIG. 6F illustrate exemplary embodiments of the turbulence generator in the present disclosure, which includes the column structures arranged in a staggered array. Compared with the column structures arranged in an aligned array as shown in FIG. 5A to FIG. 5F, the plurality of column structures of the turbulence generator 3b are composed of square columns 33a, regular triangular columns 33b, inverted triangular columns 33c, polygonal columns 33d or different wing-shaped columns 33e, 33f arranged in a staggered array, which is more helpful to increase the pressure drop of the coolant and reduce the flow rate. In other words, by adjusting the arrangement density, the pressure drop, the flow rate and the turbulence effect can also be modulated. Certainly, it should be emphasized that the present disclosure is not limited to the protruding features of the turbulence generators 3, 3a, 3b on the cover plate 20. Any protruding structure that can effectively generate a turbulent effect is applicable to the turbulence generators 3, 3a, 3b of the present disclosure to achieve an enhanced heat transfer effect. Furthermore, in other embodiment, the turbulence generators 3, 3a, 3b are movable, allowing the direction or the position thereof to be adjusted based on the flow rate or the pressure drop. The subsequent description uses only one single turbulence generator 3 to represent the various possible combinations and variations. The present disclosure is not limited thereto. This description is provided for illustrative purposes only, so explain first.

Furthermore, in the embodiment, the number of outlets 22b, 22c is two, which is greater than the number of inlet 21. When each of the outlets 22b, 22c has the same diameter as the inlet 21, the greater number of outlets 22b, 22c than the inlet 21 also means that the total outflow cross-section is greater than the total inflow cross-section. In that, it is more conducive to controlling the pressure drop and the flow rate within the chambers 23a, 23b, 23c, and the turbulence effect generated by the turbulence generator 3 corresponding to the heat dissipation fins 13. Furthermore, the coolant flowing between the inlet 21 and the outlets 22b, 22c is not limited to a single-phase cooling fluid, such as water or oil. It can also be a two-phase coolant, such as a refrigerant, to improve the cooling efficiency of the heat dissipation device through phase change. Certainly, the present disclosure is not limited thereto.

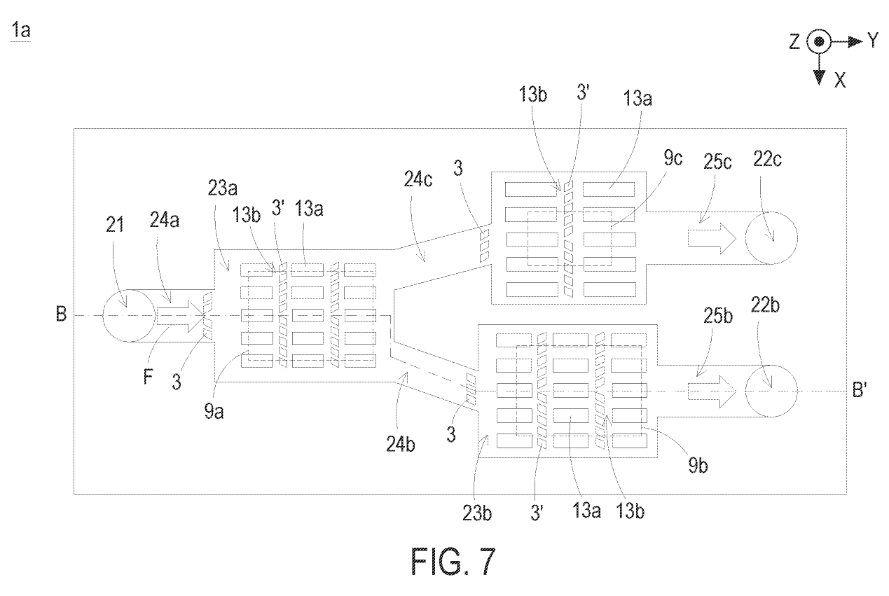

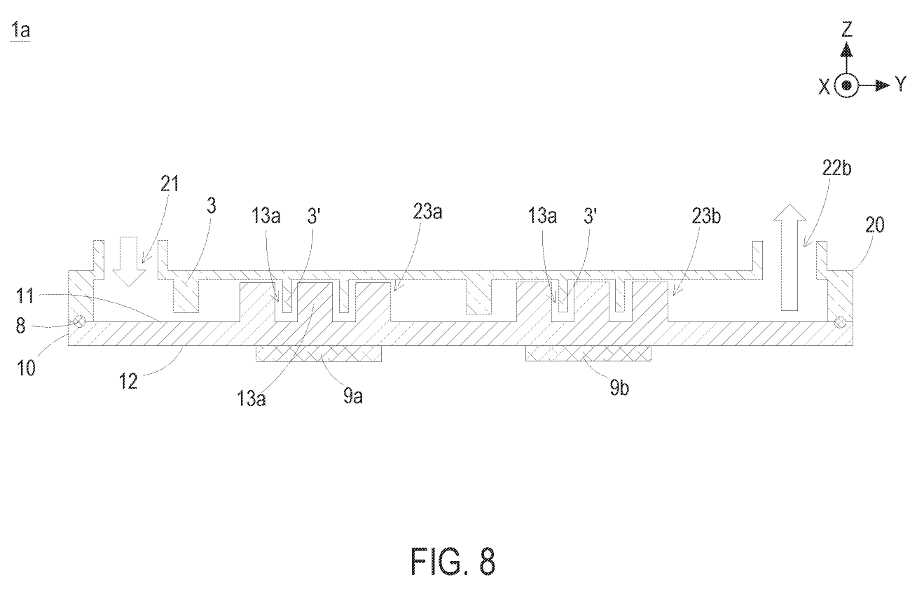

FIG. 7 is a schematic structural view illustrating an integrated cold plate cooling device according to a second embodiment of the present disclosure. FIG. 8 is a cross-sectional view of the integrated cold plate cooling device of FIG. 7 taken along line BB’. In the embodiment, the structures, elements and functions of the integrated cold plate cooling device 1a are similar to those of the integrated cold plate cooling device 1 of FIG. 1 and FIG. 2, and are not redundantly described herein. Please refer to FIG. 7 and FIG. 8. In the integrated cold plate cooling device 1a, the flow direction F of the coolant is parallel to the second direction (i.e., the Y axial direction), and the coolant flows through the plurality of chambers 23a, 23b, 23c along the second direction. In the embodiment, the plurality of heat dissipation fins 13a in the plurality of chambers 23a, 23b, 23c are extended along the second direction. The heat dissipation fins 13a in each chamber 23a, 23b, and 23c are further segmented along the second direction to form at least one spaced region 13b. Notably, in addition to the turbulence generator 3 arranged at the leading edge of the flow channel in each chamber 23a, 23b, 23c connected to the inlet 21, another turbulence generator 3’ is further arranged in the spaced region 13b within the heat dissipation fins 13a. In view of the first direction (i.e., the Z axial direction), the at least one spaced region 13b and the plurality of heat sources 9a, 9b, 9c are overlapped. Namely, the turbulence generator 3’ is corresponding to the space where the plurality of heat sources 9a, 9b, 9c exchange the heat with the corresponding heat dissipation fins 13a. Thereby, the turbulence is generated effectively and the heat transfer effect between the plurality of heat dissipation fins 13a and the plurality of heat sources 9a, 9b, 9c are enhanced. Certainly, the turbulence generator 3’ can be any combination of the aforementioned turbulence generators 3, 3a, 3b, and not redundantly described herein.

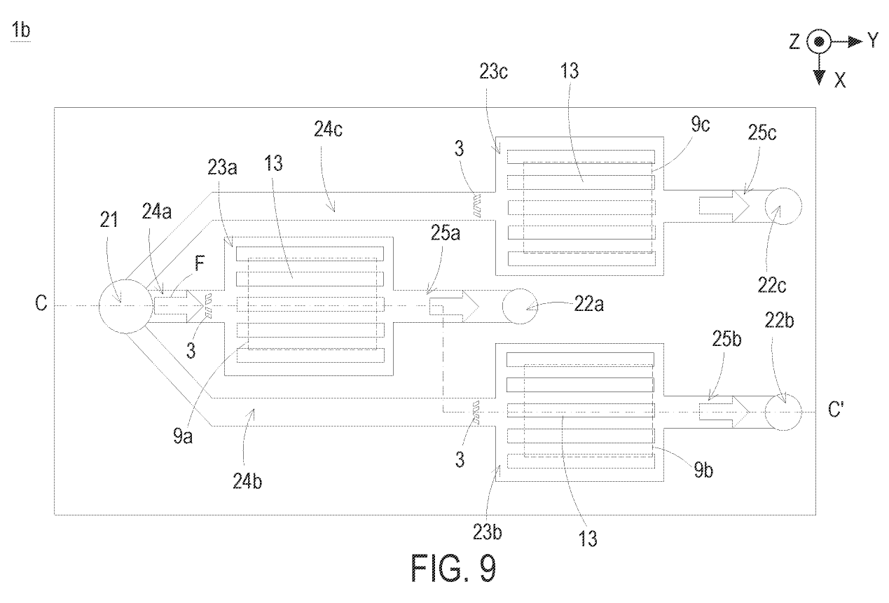

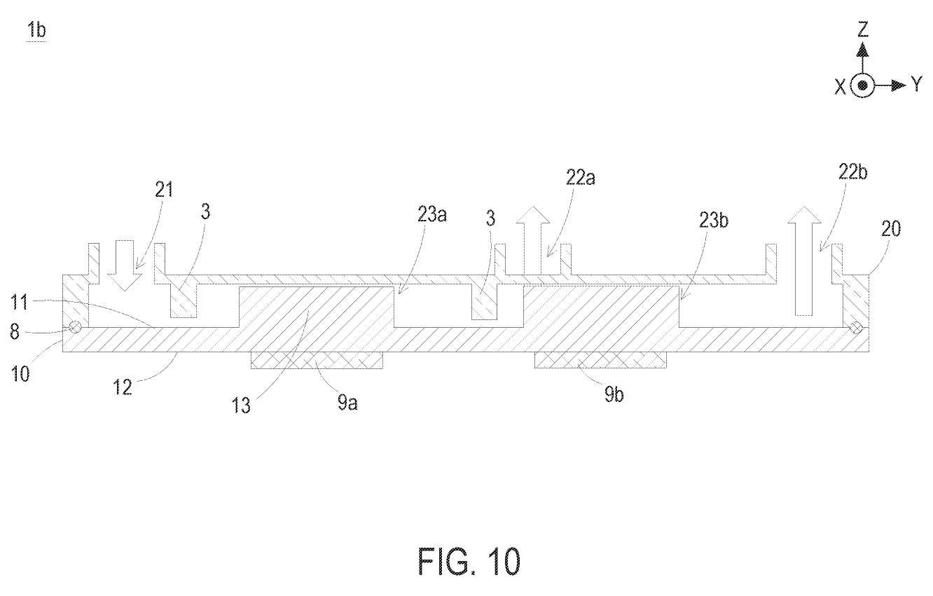

FIG. 9 is a schematic structural view illustrating an integrated cold plate cooling device according to a third embodiment of the present disclosure. FIG. 10 is a cross-sectional view of the integrated cold plate cooling device of FIG. 9 taken along line CC’. In the embodiment, the structures, elements and functions of the integrated cold plate cooling device 1b are similar to those of the integrated cold plate cooling device 1 of FIG. 1 and FIG. 2, and are not redundantly described herein. Please refer to FIG. 9 and FIG. 10. In the embodiment, the integrated cold plate cooling device 1b includes a plurality of leading channels 24a, 24b, 24c. After entering the inlet 21, the coolant is branched through the plurality of leading channels 24a, 24b, 24c and flows into the corresponding plurality of chambers 23a, 23b, 23c. In the embodiment, the plurality of leading channels 24a, 24b, 24c are respectively arranged between a leading edge of each of the plurality of chambers 23a, 23b, 23c and the inlet 21. Furthermore, in the embodiment, the number of at least one outlet 22a, 22b, 22c is the same as the number of the plurality of chambers 23a, 23b, 23c. After the coolant flows through the plurality of chambers 23a, 23b, 23c along the second direction (i.e., the Y axial direction), it further flows to the corresponding outlet 22a, 22b, 22c through the respective connected outlet channels 25a, 25b, 25c and is discharged. In the embodiment, the integrated cold plate cooling device 1b is further designed in a symmetrical arrangement, with a central axis of symmetry parallel to the second direction (i.e., the Y axial direction). Consequently, the coolant flows through the leading channels 24a, 24b, 24c stably and evenly through their respective turbulence generators 3, so that the turbulence is generated to enhance the heat transfer effect between the heat dissipation fins 13 and the heat sources 9a, 9b, 9c. Furthermore, the turbulence generators 3 at the leading edges of the chambers 23b, 23c are unaffected by the coolant being diverted from the chamber 23a, thereby providing more efficient heat dissipation for the heat sources 9b, 9c.

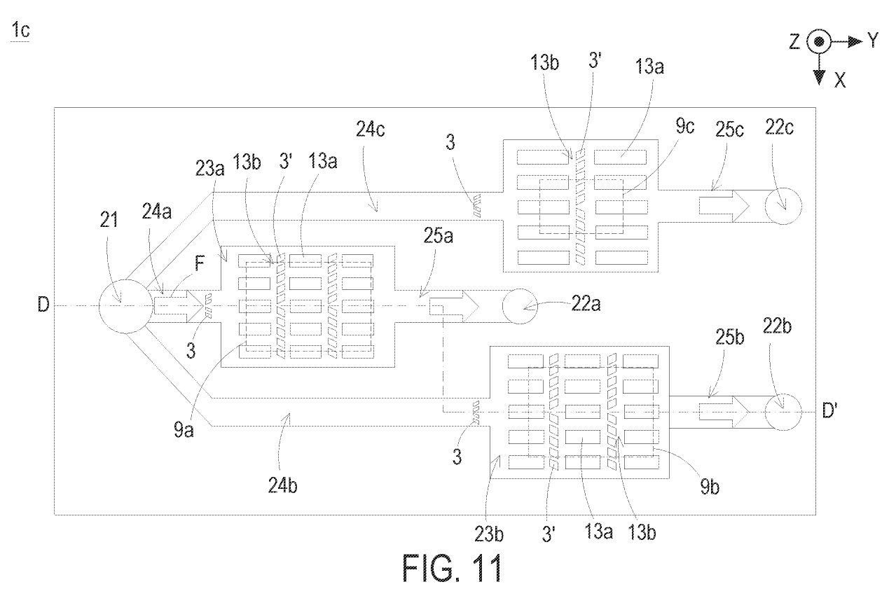

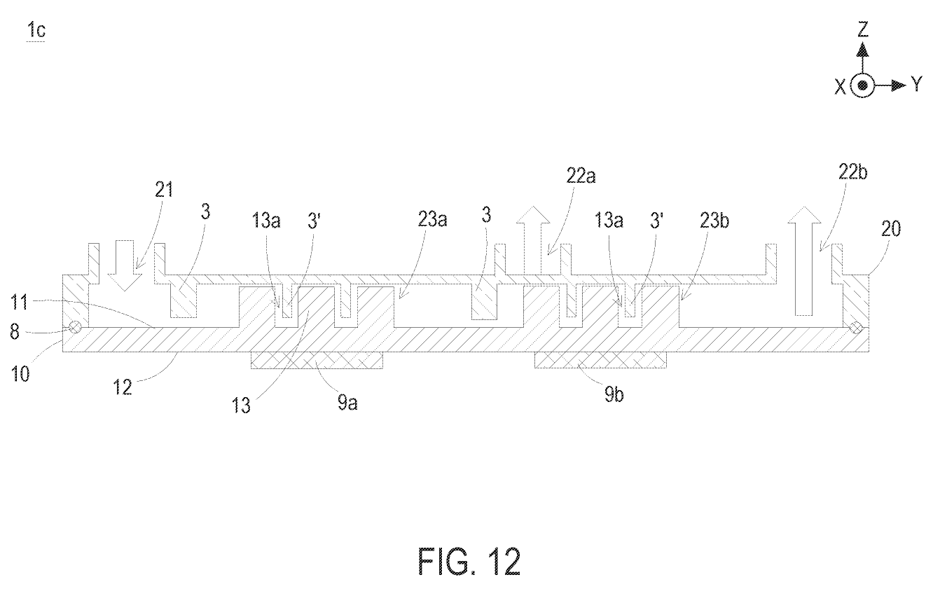

FIG. 11 is a schematic structural view illustrating an integrated cold plate cooling device according to a fourth embodiment of the present disclosure. FIG. 12 is a cross-sectional view of the integrated cold plate cooling device of FIG. 11 taken along line DD’. In the embodiment, the structures, elements and functions of the integrated cold plate cooling device 1c are similar to those of the integrated cold plate cooling device 1b of FIG. 9 and FIG. 10, and are not redundantly described herein. Please refer to FIG. 11 and FIG. 12. In the embodiment, the outlets 22a, 22b, 22c are corresponding to the chambers 23a, 23b, 23c, respectively, and are present in equal numbers. After being branched at the inlet 21, the coolant flows through the leading channels 24a, 24b, 24c to the front-end turbulence generators 3 and the internal turbulence generators 3’ corresponding to each chamber 23a, 23b, 23c. In case of that the heat sources 9a, 9b, 9c have different specifications and the heat dissipation requirements vary greatly, the front-end turbulence generators 3 and the internal turbulence generators 3’ in the corresponding chambers 23a, 23b, 23c can be adjusted according to the respective requirements without interfering with each other. Preferably but not exclusively, in the embodiment, the heat source 9b is large and the heat dissipation requirement is significant, so that the heat dissipation fins 13a can be segmented into three sections, with the internal turbulence generators 3’ located in two spaced regions 13b. Preferably but not exclusively, in the embodiment, the heat source 9c is small and the heat dissipation requirement is minimal, so that the heat dissipation fins 13a can be segmented into two sections, with the internal turbulence generators 3’ located in one single spaced region 13b. Thus, the integrated cold plate cooling device 1c can adjust the style, the arrangement and the quantity of the heat dissipation fins 13a, the front-end turbulence generators 3 and the internal turbulence generators 3’ to meet the heat dissipation requirements of different heat sources 9a, 9b, 9c. Certainly, the present disclosure is not limited thereto.

From the above, the corresponding relationship between the heat dissipation fins 13, 13a and the turbulence generators 3, 3’ of the integrated cold cooling dissipation device 1, 1a, 1b, 1c in the present disclosure are adjustable according to the heat sources 9a, 9b, 9c with the same or different heat dissipation requirements on one single printed circuit board. The chambers 23a, 23b, 23c accommodating the heat dissipating fins 13, 13a are connected in series and/or in parallel. At least the turbulence generators 3 are arranged the front edges of the heat dissipating fins 13,13a facing the flow direction F, and the turbulence generators 3’ are further arranged in the spaced regions 13b of the segmented heat dissipating fins 13a. Through the combinations of the aforementioned features, the integrated cold plate cooling devices 1, 1a, 1b, 1c can effectively control the pressure drop, the flow rate and turbulence effect of the coolant adjacent to the heat dissipation fins 13, 13a in the chambers 23a, 23b, 23c, thereby achieving the purpose of improving the overall cooling efficiency and increasing the system reliability.

In summary, the present disclosure provides an integrated cold plate cooling device. A plurality of turbulence generators are arranged to enhance the heat transfer effect and reasonably distribute the coolant flow by setting turbulence generators, so that the overall cooling efficiency and the system reliability are improved. An integrally formed metal base plate and an integrally formed plastic cover plate are tightly combined through a rubber sealing element to form a plurality of chambers in communication between an inlet and an outlet of the plastic cover plate, and simultaneously dissipate the heat from a plurality of heat sources installed on one single printed circuit board. The plurality of heat sink fins are arranged corresponding to the plurality of heat sources, so that the thermal coupling is achieved effectively. Since the plastic cover is easy to design and change the flow path, the turbulence generators are set and corresponding to the positions of the plurality of heat sink fins in the cooling chamber. The plurality of turbulence generators protrude downward from the bottom surface of the plastic cover and are located at least at a leading edge of the flow channel in communication between each of the plurality of chambers and the inlet. In other words, each turbulence generator is correspondingly positioned between each of the plurality of heat sink fins and the inlet, so as to generate the turbulence effectively to enhance the heat transfer. The turbulence generator disposed on the plastic cover is composed of multiple protruding features, which can effectively generate turbulence to enhance the heat transfer effect. The structure unit of the turbulence generator includes a square column, a triangular column, a quadrilateral column, a polygonal column, a circular column, a cone, a round-headed column, an inclined column, a wing-shaped column, a curved fin, a transverse rib, an inclined rib, a V-shaped rib, or a W-shaped rib. The cross-section of the rib structure can be, for example, square, triangle, right triangle, rounded rectangle or arc. The style, the quantity and the arrangement can be combined and varied according to the practical requirements. In addition, the turbulence generators are placed at the entrance of the heat-sink-fin area or in the spaced region between the heat sink fins in the chamber. By adjusting the style, the number and the arrangement of the turbulence generators, the pressure drop in the chamber with the heat-sink-fin area can be controlled, thereby achieving a reasonable distribution of the coolant flow. Furthermore, the turbulence generator can be a movable structure, allowing adjusting the direction or the position according to the flow rate or the pressure drop. On the other hand, the outlet for the coolant can be arranged in multiple locations to match the heat source of the chip layout, but is not limited thereto. Furthermore, the coolant flowing between the inlet and the outlet is not limited to a single-phase cooling fluid, such as water or oil. It can also be a two-phase coolant, such as a refrigerant, to improve the cooling efficiency of the heat dissipation device through phase change. Certainly, the present disclosure is not limited thereto.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An integrated cold plate cooling device, comprising:
a base plate comprising a top surface, a bottom surface and a plurality of heat dissipation fins, wherein the top surface and the bottom surface are arranged opposite to each other in a first direction, the bottom surface is thermally coupled to a plurality of heat sources, and the plurality of heat dissipation fins are arranged on the top surface and spatially corresponding to the plurality of heat sources; and
a cover plate comprising an inlet, at least one outlet and a plurality of turbulence generators, wherein the cover plate is assembled to the top surface of the base plate along the first direction, and a plurality of chambers are formed, wherein the plurality of chambers are configured to respectively accommodate the plurality heat dissipation fins and in communication between the inlet and the at least one outlet, wherein the plurality of turbulence generators protrude from the cover plate toward the base plate, and each of the plurality of turbulence generators is correspondingly arranged between one of the plurality of heat dissipation fins and the inlet.

2. The integrated cold plate cooling device according to claim 1, wherein the base plate is formed by integrally molding a metal material, and the cover plate is formed by integrally molding a plastic material.

3. The integrated cold plate cooling device according to claim 1, wherein the plurality of heat dissipation fins and the plurality of heat sources are overlapped in view of the first direction.

4. The integrated cold plate cooling device according to claim 1, wherein the plurality of heat dissipation fins and the plurality of turbulence generators are misaligned in view of the first direction.

5. The integrated cold plate cooling device according to claim 1, wherein a coolant flows through the plurality of chambers along a second direction respectively, and the second direction is perpendicular to the first direction, wherein the plurality of heat dissipation fins are extended along the second direction, and openings of the inlet and the at least one outlet face the first direction.

6. The integrated cold plate cooling device according to claim 1, wherein the cover plate comprises an outer peripheral wall, which is tightly combined with the base plate through a rubber sealing element.

7. The integrated cold plate cooling device according to claim 1, wherein the plurality of turbulence generators comprises at least one rib structure selected from the group consisting of a transverse rib, an inclined rib, a V-shaped rib, a W-shaped rib and a combination thereof.

8. The integrated cold plate cooling device according to claim 7, wherein the at least one rib structure includes a cross-section selected from one of the group consisting of a square, a rectangle, a triangle, a right triangle, a rounded rectangle and a combination thereof, the plurality of heat dissipation fins are extended along a second direction, the second direction is perpendicular to the first direction, and an extension direction of the at least one rib structure is not parallel to the second direction.

9. The integrated cold plate cooling device according to claim 7, wherein a tip is formed at the middle section of each of the V-shaped ribs, and the tip faces the inlet or the at least one outlet.

10. The integrated cold plate cooling device according to claim 7, wherein a tip is formed at the middle section of each of the W-shaped ribs, and the tip faces the inlet or the at least one outlet.

11. The integrated cold plate cooling device according to claim 1, wherein the plurality of turbulence generators comprises a plurality of column structures selected from the group consisting of a square column, a triangular column, a quadrilateral column, a polygonal column, a circular column, a cone, a round-headed column, an inclined column, a wing-shaped column, an arc-shaped fin and a combination thereof.

12. The integrated cold plate cooling device according to claim 11, wherein the plurality of column structures are arranged in an aligned array or a staggered array.

13. The integrated cold plate cooling device according to claim 1, wherein a number of the at least one outlet is greater than a number of the inlet.

14. The integrated cold plate cooling device according to claim 1, wherein a number of the at least one outlet is equal to a number of the plurality of chambers, a coolant flows through the plurality of chambers along a second direction and is discharged through a corresponding one of the at least one outlet, and the second direction is perpendicular to the first direction.

15. The integrated cold plate cooling device according to claim 1, wherein a coolant flows through the plurality of chambers along a second direction, and the second direction is perpendicular to the first direction, wherein the plurality of heat dissipation fins are extended along the second direction in the plurality of chambers and segmented to form at least one spaced region, wherein one of the plurality of turbulence generators is located in the at least one spaced region.

16. The integrated cold plate cooling device according to claim 15, wherein the at least one spaced region and the plurality of heat sources are overlapped in view of the first direction.

17. The integrated cold plate cooling device according to claim 1, further comprising a plurality of leading channels, wherein the inlet is branched into the plurality of chambers through the plurality of leading channels.

18. The integrated cold plate cooling device according to claim 1, further comprising a plurality of leading channels, wherein the plurality of leading channels are respectively arranged between a leading edge of each of the plurality of chambers and the inlet.

19. The integrated cold plate cooling device according to claim 1, wherein a coolant flows through the plurality of chambers along a second direction, and the second direction being perpendicular to the first direction, wherein the plurality of chambers in communication between the inlet and the at least one outlet are symmetrically arranged, with a central axis of symmetry parallel to the second direction.
